(19) United States
(12) Patent Application Publication
(10) Pub. No.: US 2025/0117066 A1
(43) Pub. Date: Apr. 10, 2025

(54) CIRCUIT BOARD AND SWITCH SWITCHING METHOD THEREOF

(71) Applicant: Acer Incorporated, New Taipei City (TW)

(72) Inventors: Tsung-Mao Chen, New Taipei City (TW); Ming-Feng HSIEH, New Taipei City (TW); Yuan-Yi Li, New Taipei City (TW)

(73) Assignee: Acer Incorporated, New Taipei City (TW)

(21) Appl. No.: 18/799,604

(22) Filed: Aug. 9, 2024

(30) Foreign Application Priority Data
Oct. 5, 2023 (TW) 112138249

(51) Int. Cl. G06F 1/3287; H05K 1/02; H05K 1/18

(52) U.S. Cl. CPC G06F 1/3287; H05K 1/0215; H05K 1/18; H05K 2201/10053; H05K 2201/10166; H05K 2201/10189; H05K 2201/10212

(57) ABSTRACT

A circuit board includes a platform controller hub (PCH), a peripheral component connector and a switch. The PCH includes a clock request pin and a GPIOB pin. The peripheral component connector includes a connector pin. The switch is controlled by the GPIOB pin and is coupled between a low potential and a line between the connector pin and the clock request pin and is configured to: conduct the line and the low potential based on a high potential of the GPIOB pin; and disconnect the line and the low potential based on the low potential of the GPIOB pin.

This application claims the benefit of Taiwan application Serial No. 112138249, filed Oct. 5, 2023, the subject matter of which is incorporated herein by reference.

### BACKGROUND OF THE INVENTION

### Field of the Invention

The invention relates in general to a circuit board and a switch switching method thereof.

### Description of the Related Art

Based on trend of the energy-saving, some new graphics cards have recently provided an energy-saving function. When a graphics card that supports the energy-saving function is inserted into a circuit board, a manual line-jumping set to the circuit board is needed to support the graphics card with energy-saving function. However, the manual line-jumping requires the host casing to be disassembled before the manual line-jumping set is performed on the circuit board, which is quite inconvenient in operation.

### SUMMARY OF THE INVENTION

According to an embodiment of the present invention, a circuit board is provided. The circuit board includes a platform controller hub, a peripheral component connector and a switch. The platform controller hub includes a clock request pin and a general-purpose input/output B (GPIOB) pin. The peripheral component connector includes a first connector pin. The switch is controlled by the GPIOB pin and coupled between a low potential and a line between the first connector pin and the clock request pin, and configured to connect the line with the low potential based on a high potential of the GPIOB pin, and disconnect the line from the low potential based on a low potential of the GPIOB pin.

According to another embodiment of the present invention, a circuit board is provided. The circuit board includes a platform controller hub, a peripheral component connector a switch. The platform controller hub includes a clock request pin and a GPIOB pin. The peripheral component connector includes a first connector pin. The switch is controlled by the GPIOB pin and coupled between a low potential and a line between the first connector pin and the clock request pin.

According to another embodiment of the present invention, a switch switching method for a circuit board is provided. The switch switching method includes the following steps: connecting the line with the low potential by the circuit board based on the high potential of the GPIOB pin; and disconnecting the line from the low potential by the circuit board based on the low potential of the GPIOB pin.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a functional block diagram of a circuit board 100 according to an embodiment of the present invention;

FIG. 2A illustrates a circuit diagram of a switch 130 in FIG. 1 being turned on;

FIG. 2B illustrates a circuit diagram of the switch 130 in FIG. 2A being turned off;

FIG. 3 illustrates a signal diagram of a clock request pin 111 in FIG. 2B; and

FIG. 4 illustrates a flow chart of a switch switching method for a circuit board 100 in FIG. 1.

### DETAILED DESCRIPTION OF THE INVENTION

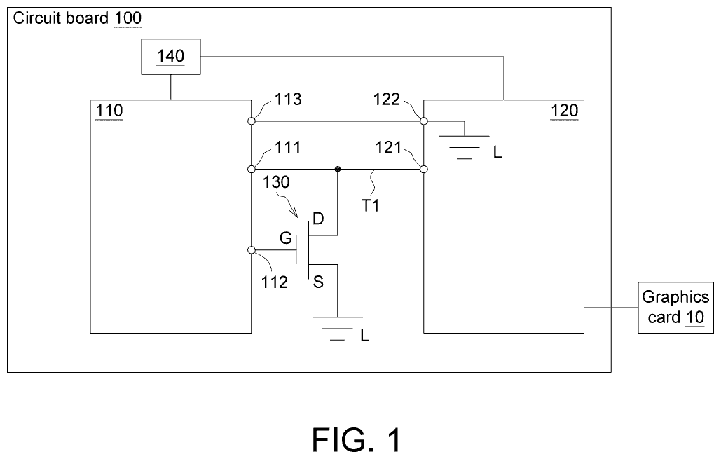

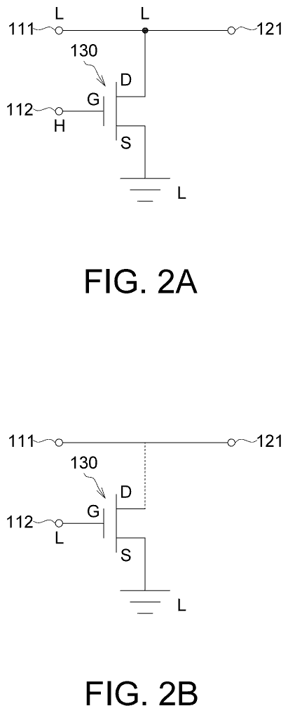

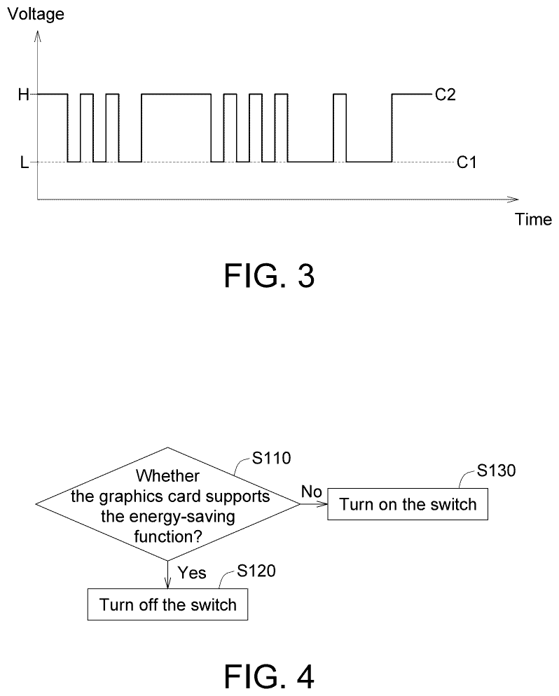

Referring to FIGS. 1 to 3, FIG. 1 illustrates a functional block diagram of a circuit board 100 according to an embodiment of the present invention, FIG. 2A illustrates a circuit diagram of a switch 130 in FIG. 1 being turned on, FIG. 2B illustrates a circuit diagram of the switch 130 in FIG. 2A being turned off, and FIG. 3 illustrates a signal diagram of a clock request pin 111 in FIG. 2B.

The circuit board 100 may be applied to a desktop computer host, but the embodiments of the present invention are not limited to this.

As illustrated in FIG. 1, the circuit board 100 includes a platform controller hub (PCH) 110, a peripheral component connectors 120, a switch 130 and a basic input/output system (BIOS) 140. The platform controller hub 110 includes a clock request (CLKREQ) pin 111 and a general-purpose input/output B (GPIOB) pin 112. The peripheral component connector 120 includes a first connector pin 121. The switch 130 is controlled by the GPIOB pin 112 and is coupled between a line T1 between the first connector pin 121 and the clock request pin 111 and a low potential L. As a result, as illustrated in FIG. 2A, based on the conduction of the switch 130, the first connector pin 121 and the clock request pin 111 may be electrically connected to the low potential. As illustrated in FIG. 2B, based on the non-conduction of the switch 130 (the non-conduction is represented as a dotted line), the first connector pin 121 and the clock request pin 111 are not electrically connected to the low potential L. In an embodiment, the low potential L is, for example, a grounding potential, but the embodiment of the present invention is not limited to this.

As illustrated in FIGS. 1 and 2B, when the first connector pin 121 and the clock request pin 111 are not electrically connected to the low potential L, a graphics card 10 (supporting an energy-saving mode) electrically connected to the peripheral component connector 120 may communicate with the platform controller hub 110 by the energy-saving mode. Furthermore, when the graphics card 10 electrically connected to the peripheral component connector 120 supports the energy-saving mode, the switch 130 may be selectively turned off to support the energy-saving mode of the graphics card 10. When the graphics card 10 electrically connected to the peripheral device connector 120 does not support the power saving mode, the switch 130 may be selectively turned on.

Furthermore, when the clock request pin 111 is electrically connected to the low potential L, it means that the graphics card 10 requests the platform controller hub 110 to transmit the clock through the first connector pin 121 of the peripheral component connector 120, and accordingly the peripheral device connector 120 transmits the clock signal to the peripheral component connector 120. In other words, if the clock request pin 111 is constantly electrically connected to the low potential L, the platform controller hub 110 will constantly transmit the clock signal to the peripheral device connector 120, which results in unnecessary power consumption. In contrast to this application, the switch 130 may be selectively turned off, so that the clock request pin 111 is not electrically connected to the low potential L, which may reduce unnecessary energy consumption. In addition, when the clock request pin 111 is not electrically connected to the low potential L, the graphics card 10 that supports the power saving mode will transmit a low potential signal to the clock request pin 111 when necessary (for example, when a clock signal synchronization operation is required).

As illustrated in FIG. 3, a curve C1 represents a signal diagram of the clock request pin of a conventional circuit board that omits the switch 130, and a curve C2 represents a signal diagram of the clock request pin 111 of the circuit board 100 according to the embodiment of the present invention. It may be seen from the curve C1 that the clock of the conventional circuit board that omits the switch 130 requires that the pin constantly maintains a low potential L, and thus it causes the platform controller hub 110 to constantly transmit the clock signal to the peripheral device connector 120, causing unnecessary power consumption. It may be seen from the curve C2 that the clock pulse requirement pin 111 of the circuit board 100 of the embodiment of the present invention is not electrically connected to the first connector pin 121, and therefore it does not maintain the low potential normally, so that the graphics card 10 supporting the energy-saving mode may transmit the signal of the low potential to the clock request pin 111 when the clock signal synchronization operation is required. It may be seen from the curve C2 that when the graphics card 10 supporting the energy-saving mode does not need the clock signal synchronization operation, the clock request pin 111 may be maintained at a high potential H (no clock signal is transmitted), so the technical effect of energy saving may be achieved.

As illustrated in FIG. 1, the platform controller hub 110 further includes a GPIOA pin 113, the peripheral component connector 120 further includes a second connector pin 122, the GPIOA pin 113 and the second connector pin 122 are coupled. The GPIOA pin 113 may detect the signal of the second connector pin 122 to determine whether the graphics card 10 is inserted into the peripheral component connector 120. In the present embodiment, the second connector pin 122 is not coupled to the clock request pin 111, so that the clock request pin 111 cannot be electrically connected to the low potential L constantly. Furthermore, the second connector pin 122 of the peripheral device connector 120 is electrically connected to the low potential L. As a result, if the second connector pin 122 is coupled to the clock request pin 111, the clock request pin 111 is constantly electrically connected to the low potential (when the graphics card 10 is inserted into the peripheral component connector 120), and thus the power-saving mode of the graphics card can't be supported.

In an embodiment, the peripheral component connector 120 is, for example, a Peripheral Component Interconnect Express (PCIE), the first connector pin 121 is, for example, a B12 pin of the PCIE, and the second connector pin 122 is, for example, a B17 pin of the PCIE.

The BIOS 140 is configured to determine whether the graphics card 10 (for example, a VGA card or a graphics card that supports the PCIE protocol) connected to the peripheral component connector 120 supports the energy-saving function; based on the graphics card 10 supporting the energy-saving function, thru of the switch 130, as illustrated in FIG. 2B; and the BIOS 140 is further configured to turn on the switch 130 based on the fact that the graphics card 10 does not support the energy-saving function, as illustrated in FIG. 2A.

As illustrated in FIG. 1, the switch 130 includes a gate G, a drain D and a source S. The gate G is electrically coupled to the GPIOB 112, the drain D is electrically coupled to the line T1, and the source S is electrically coupled to low potential. The switch 130 is configured to: conduct the line T1 with the low potential L based on the high potential of the GPIOB pin 112; and disconnect the line T1 from the low potential L based on the low potential of the GPIOB pin 113.

Referring to FIG. 4, FIG. 4 illustrates a flow chart of a switch switching method of the circuit board 100 in FIG. 1.

In step S110, referring to FIG. 1, the GPIOA pin 113 may detect the signal of the second connector pin 122 to determine whether the graphics card 10 is inserted into the peripheral component connector 120. When the graphics card 10 is inserted into the peripheral device connector 120, the BIOS 140 may determine the type of the graphics card 10 connected to the peripheral device connector 120. For example, whether the graphics card 10 supports the energy-saving function. If the graphics card 10 supports the energy-saving function, the process proceeds to step S120; if the graphics card 10 does not support the energy-saving function, the process proceeds to step S130.

In step S120, referring to FIG. 2B, when the graphics card 10 has the energy-saving function, the potential of the GPIOB pin 112 may be set to the low potential to turn off the switch 130, thereby supporting the energy-saving function of the graphics card 10.

In step S130, referring to FIG. 2A, when the graphics card 10 does not have the energy-saving function, the potential of the GPIOB pin 112 may be set to the high potential for turning on the switch 130 and enable the clock request pin 111 to be electrically connected to the low potential L, thereby enabling the platform controller hub 110 to constantly transmit the clock signal to the peripheral component connector 120 to provide the graphics card 10 without the energy-saving function to perform the clock signal synchronization operation at any time.

In summary, embodiments of the present invention provide a circuit board and a switch switching method thereof, which may selectively support graphics cards with energy-saving mode and the graphics card without energy-saving mode through the switching of the switch.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. A circuit board, comprising:
a platform controller hub (PCH), comprising a clock request pin and a general-purpose input/output B (GPIOB) pin; and
a peripheral component connector, comprising a first connector pin;
a switch controlled by the GPIOB pin and coupled between a low potential and a line between the first connector pin and the clock request pin, and configured to:
connect the line with the low potential based on a high potential of the GPIOB pin; and
disconnect the line from the low potential based on a low potential of the GPIOB pin.

2. The circuit board as claimed in claim 1, wherein the switch comprises a gate, a drain and a source, the gate is electrically coupled to the GPIOB pin, and the drain is electrically coupled to the line, and the source is electrically coupled to the low potential.

3. The circuit board as claimed in claim 1, further comprising:
a basic input/output system (BIOS), configured to:
determine whether a graphics card connected to the peripheral component connector supports an energy-saving function; and
based on the graphics card supporting the energy-saving function, turn off the switch.

4. The circuit board as claimed in claim 3, wherein the BIOS is further configured for:
based on the graphics card not supporting the energy-saving function, turn on the switch.

5. The circuit board as claimed in claim 1, wherein the low potential is a grounding potential.

6. The circuit board as claimed in claim 1, wherein the platform controller hub further comprises a general-purpose input/output A (GPIOA) pin, the peripheral component connector further comprises a second connector pin, and the GPIOA pin is coupled to the second connector pin.

7. The circuit board as claimed in claim 6, wherein the peripheral component connector is a peripheral component interconnect express (PCIE), and the second connector pin is a B17 pin of the peripheral component interconnect express.

8. The circuit board as claimed in claim 1, wherein the peripheral component connector is a peripheral component interconnect express.

9. The circuit board as claimed in claim 8, wherein the first connector pin is a B12 pin of the peripheral component interconnect express.

10. A circuit board, comprising:
a platform controller hub, comprising a clock request pin and a GPIOB pin;
a peripheral component connector, comprising a first connector pin; and
a switch, controlled by the GPIOB pin and coupled between a low potential and a line between the first connector pin and the clock request pin.

11. The circuit board as claimed in claim 10, wherein the switch comprises a gate, a drain and a source, the gate is electrically coupled to the GPIOB pin, and the drain is electrically coupled to the line, and the source is electrically coupled to the low potential.

12. The circuit board as claimed in claim 10, further comprising:
a BIOS configured to:
determine whether a graphics card connected to the peripheral component connector supports an energy-saving function; and
based on the graphics card supporting the energy-saving function, turn off the switch

13. The circuit board as claimed in claim 12, wherein the BIOS is further configured to:
based on the graphics card not supporting the energy-saving function, turn on the switch.

14. The circuit board as claimed in claim 10, wherein the low potential is a grounding potential.

15. The circuit board as claimed in claim 10, wherein the platform controller hub further comprises a GPIOA pin, the peripheral component connector further comprises a second connector pin, and the GPIOA pin is coupled to the second connector pin.

16. The circuit board as claimed in claim 15, wherein the peripheral component connector is a peripheral component interconnect express, and the second connector pin is a B17 pin of the peripheral component interconnect express.

17. The circuit board as claimed in claim 10, wherein the peripheral component connector is a peripheral component interconnect express.

18. The circuit board as claimed in claim 17, wherein the first connector pin is a B12 pin of the peripheral component interconnect express.

19. A switch switching method for a circuit board as claimed in claim 1, comprising:
connecting the line with the low potential by the circuit board based on the high potential of the GPIOB pin; and
disconnecting the line from the low potential by the circuit board based on the low potential of the GPIOB pin.

20. The switch switching method as claimed in claim 19, further comprising:
determining whether a graphics card connected to the peripheral component connector supports an energy-saving function by a BIOS; and
turning off the switch based on the graphics card supporting the energy-saving function.
